(19) United States
(12) Patent Application Publication
(10) Pub. No.: US 2016/0315097 A1
(43) Pub. Date: Oct. 27, 2016

(54) THREE-DIMENSIONAL DOUBLE DENSITY NAND FLASH MEMORY

(71) Applicant: NEO Semiconductor, Inc., San Jose, CA (US)

(72) Inventor: Fu-Chang Hsu, San Jose, CA (US)

(21) Appl. No.: 15/081,737

(22) Filed: Mar. 25, 2016

Related U.S. Application Data
(60) Provisional application No. 62/138,844, filed on Mar. 26, 2015.
(60) Provisional application No. 62/139,610, filed on Mar. 27, 2015.
(60) Provisional application No. 62/255,506, filed on Nov. 15, 2015.

(51) Int. Cl. H01L 27/115

(52) U.S. Cl. CPC H01L 27/11582; H01L 27/11565; H01L 27/1157

(57) ABSTRACT

A three-dimensional double-density NAND flash memory device is disclosed. In one aspect, an apparatus includes a three dimensional stacked configuration of word line layers separated by insulating layers. The stacked configuration includes a selected number of the word line layers. The apparatus also includes an array of NAND strings deposited within the stacked configuration and perpendicular to a top surface of the stacked configuration. Each NAND string includes a charge-trapping layer that extends through the selected number of word line layers. The apparatus also includes one or more slits through the stacked configuration that divide each word line layer into a plurality of word line regions. The charge-trapping layer of each NAND string is coupled to two word line regions in each word line layer to form two charge-trapping regions to store two data bits in each word line layer.

### PRIORITY

This application claims the benefit of priority based upon U.S. Provisional Patent Application having application Ser. No. 62/255,506, filed on Nov. 15, 2015, and entitled “3D Double-Density NAND Flash Memory,” U.S. Provisional Patent Application having application Ser. No. 62/139,610, filed on Mar. 27, 2015, and entitled “3D Double-Density NAND Flash Memory,” and U.S. Provisional Patent Application having application Ser. No. 62/138,844, filed on Mar. 26, 2015, and entitled “3D Double-Density NAND Flash Memory,” all of which are hereby incorporated herein by reference in their entireties.

### FIELD OF THE INVENTION

The exemplary embodiments of the present invention relate generally to the field of semiconductor and integrated circuits, and more specifically to memory and storage devices.

### BACKGROUND OF THE INVENTION

Nonvolatile memory, such as NAND based flash memory, has become a widely used storage memory for various devices and systems. The unique cell and array structures of flash memory provide small cell size, high density, low write current, and high throughput. Some exemplary applications of flash memory include personal computers, PDAs, digital audio players, digital cameras, mobile phones, synthesizers, video games, scientific instrumentation, industrial robotics, and medical electronics.

With recent developments in semiconductor processing technology, the transformation from two-dimensional (“2D”) to three-dimensional (“3D”) NAND flash memory has becomes possible. A 3D NAND flash memory, for example, can reach storage capacities of 128 to 256 gigabit (“Gb”). Due to its 3D stacked structure, 3D NAND flash memory can increase storage density and overcome shrinkage limitations beyond 10 nm, which is a limitation associated with the 2D NAND flash process. Thus, 3D NAND flash memory has become very attractive when compared to 2D NAND flash memory.

Unfortunately, conventional 3D NAND structures can only store one data bit per cell, which makes it very difficult to achieve storage capacity greater than 256 Gb. It is therefore desirable to have a 3D NAND flash memory device with increased storage capacity.

### SUMMARY

In various exemplary embodiments, a 3D Double-Density (DD) NAND flash memory is disclosed. In order to increase storage density, novel cell and array structures are used to store two data bits in one NAND cell without increasing the existing array size. Therefore, the memory density is doubled with the same die size. The fundamental process steps of manufacturing the novel cell and array are also disclosed

In one aspect, an apparatus includes a three dimensional stacked configuration of word line layers separated by insulating layers. The stacked configuration includes a selected number of the word line layers. The apparatus also includes an array of NAND strings deposited within the stacked configuration and perpendicular to a top surface of the stacked configuration. Each NAND string includes a charge-trapping layer that extends through the selected number of word line layers. The apparatus also includes one or more slits through the stacked configuration that divide each word line layer into a plurality of word line regions. Due to the location of the slits, the charge-trapping layer of each NAND string is coupled to two word line regions in each word line layer to form two charge-trapping regions to store two data bits in each word line layer.

Additional features and benefits of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1 shows a stacked cell structure of a conventional 3D NAND flash memory;

FIGS. 2A-Z show exemplary embodiments of a novel 3D Double-Density NAND flash memory;

FIG. 3 shows an exemplary embodiment of a cell channel with interfaces to multiple word lines that stores two data bits;

FIGS. 4A-4F shows exemplary embodiments of process steps used to form the 3D Double-Density NAND array structure shown in FIG. 2A;

FIGS. 5A-5O show exemplary embodiments of process steps to form the 3D DD NAND array structure shown in FIG. 2A;

FIGS. 6A-6D show exemplary embodiments of word line ‘slit’ patterns for use with embodiments of the 3D Double-Density NAND array;

FIG. 7 shows a conventional 3D NAND flash memory array structure;

FIGS. 8A-B show exemplary embodiments of 3D Double-Density NAND flash memory array structures;

FIGS. 9A-B shows structural and schematic views of a conventional 3D NAND cell string; and

FIGS. 10A-C shows structural and schematic views of a 3D Double-Density NAND cell string.

### DETAILED DESCRIPTION

Exemplary embodiments of the present invention are described herein in the context of a process, device, method, and apparatus for providing semiconductor storage devices.

Those of ordinary skilled in the art will realize that the following detailed description is illustrative only and is not intended to be in any way limiting. Other embodiments of the present invention will readily suggest themselves to such skilled persons having the benefit of this disclosure. Reference will now be made in detail to implementations of the exemplary embodiments of the present invention as illustrated in the accompanying drawings. The same reference indicators (or numbers) will be used throughout the drawings and the following detailed description to refer to the same or like parts.

Those of ordinary skills in the art will now realize that the devices described herein may be formed on a conventional semiconductor substrate or they may as easily be formed as a thin film transistor (TFT) above the substrate, or in silicon on an insulator (SOI) such as glass (SOG), sapphire (SOS), or other substrates as known to those of ordinary skills in the art. Such persons of ordinary skills in the art will now also realize that a range of doping concentrations around those described above will also work. Essentially, any process capable of forming pFETs and nFETs will work. Doped regions may be diffusions or they may be implanted.

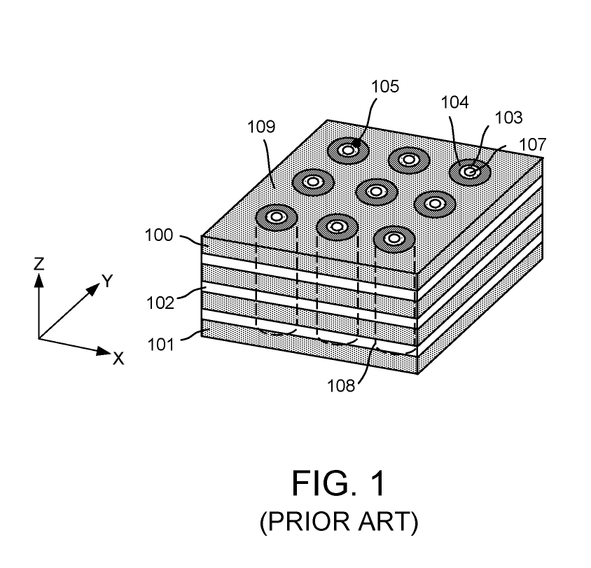

FIG. 1 shows a stacked cell structure of a conventional 3D NAND flash memory. The conventional 3D NAND includes multiple polysilicon or metal layers (ML) that function as word lines (WL), such as WL 100 and WL 101. Insulation layers (e.g., 102), such as an oxide, are positioned between the word lines to form a stacked configuration. For example, the word line layers and the insulating layers are stacked in the Z direction up to a particular number of layers or height. An array of openings 108 is etched in the top surface 109 of the stacked configuration and the openings extend for the height of the stack. NAND strings are deposited within the openings. A silicon region 103 (or polysilicon) runs vertically and functions as the NAND string's cell channel. A charge-trapping layer 104, such as an ONO (Oxide-Nitride-Oxide) layer, surrounds the cell channel 103 and is used to trap electrons or holes for data storage. An insulator layer 107, such as oxide, may be located in the center of the cell channel depending on the technology used. Each storage cell is formed at the intersection of a WL and the charge-trapping layer of each NAND string cell. Because each WL layer completely surrounds the charge-trapping layer 104, each storage cell stores charges that represent one bit of data, as shown at 105, for a SLC (Single-Level-Cell) structure shown. It should be noted that NAND flash memory may also have MLC (Multiple-Level-Cell) structures or TLC (Triple-Level-Cell) structures that store 2 or 3 bits, respectively, at each cell.

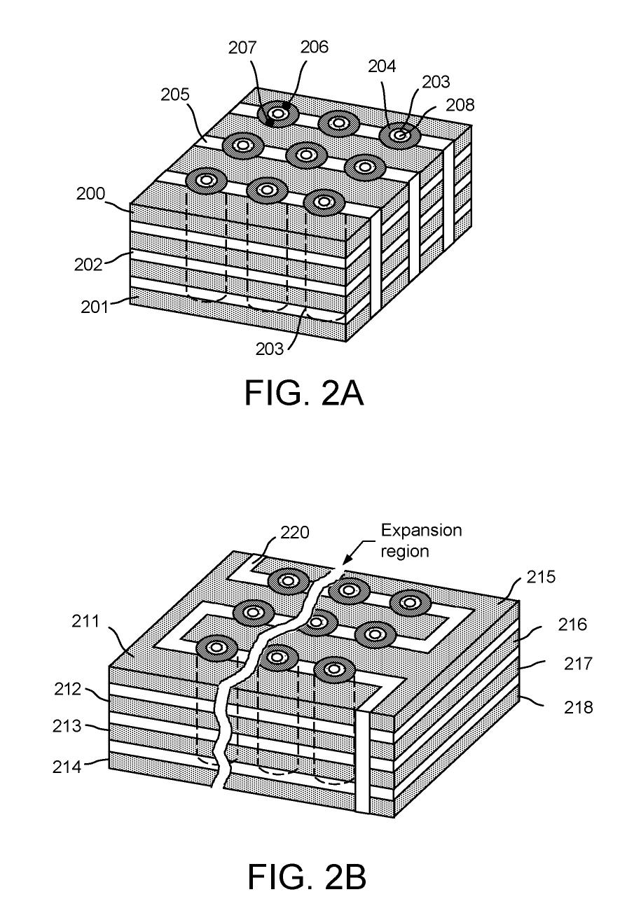

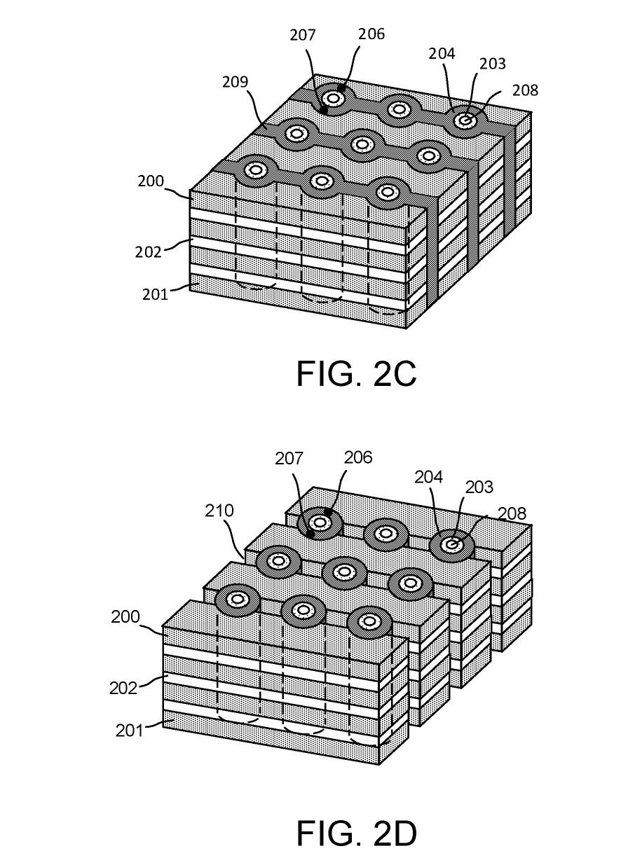

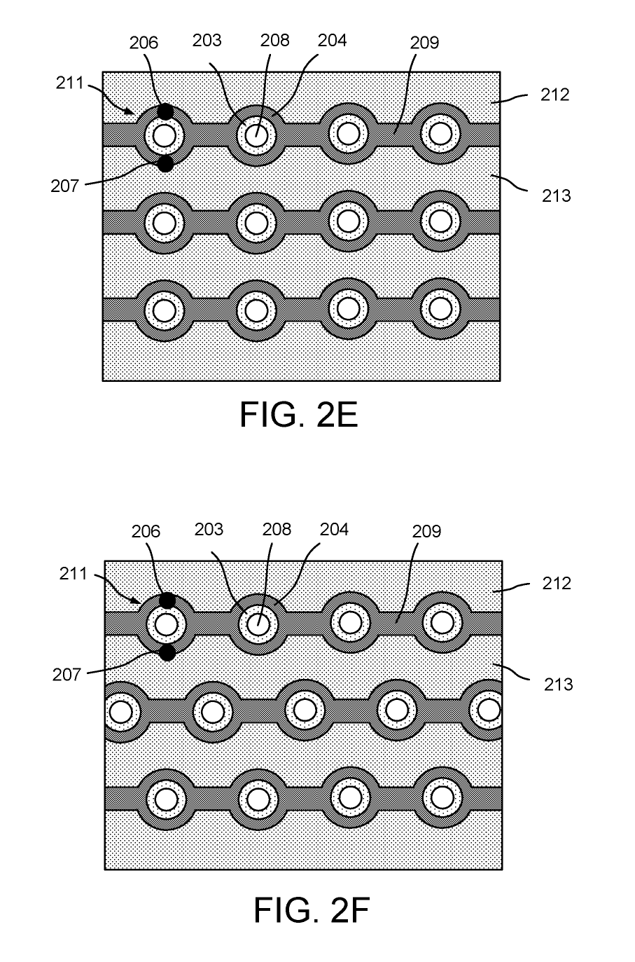

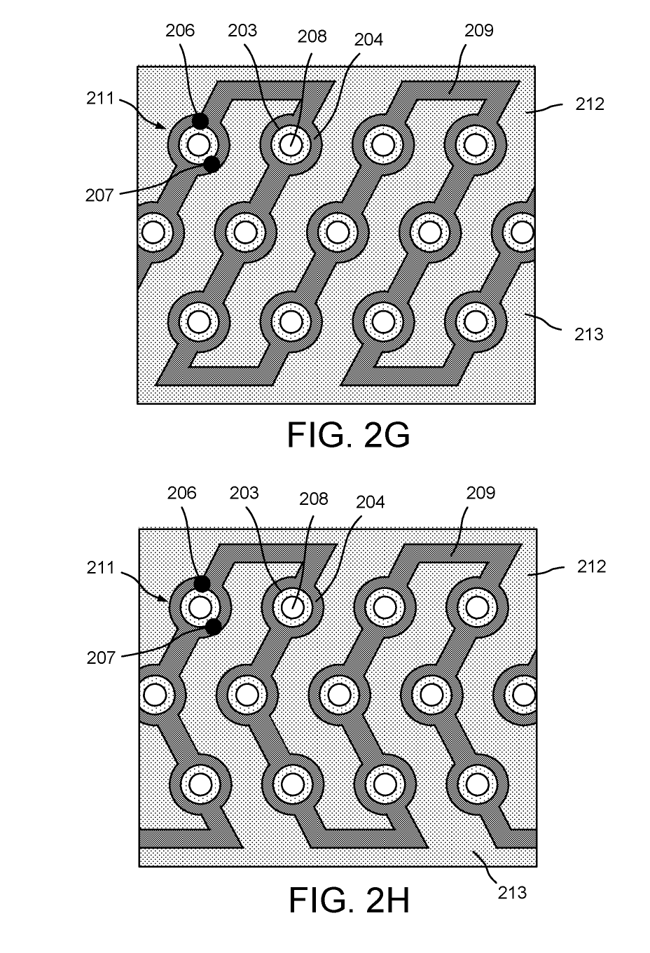

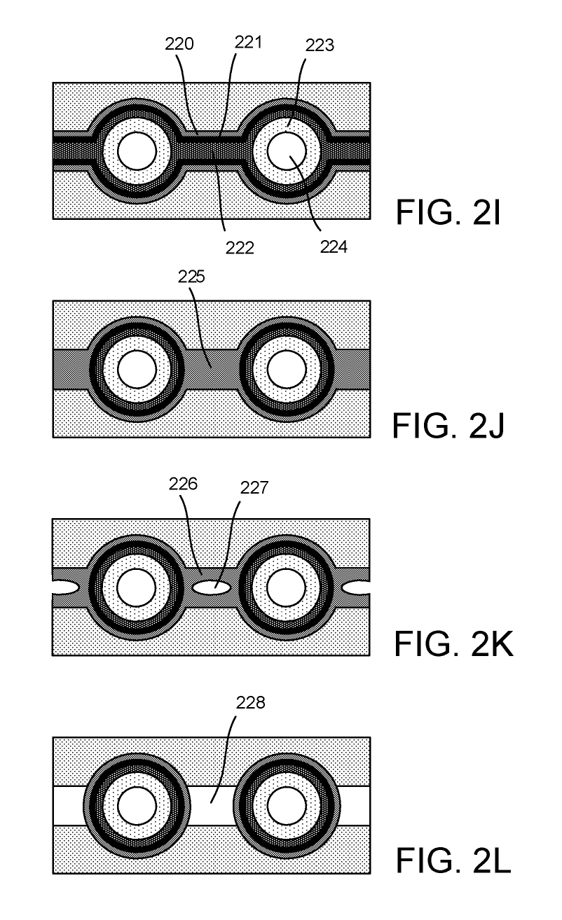

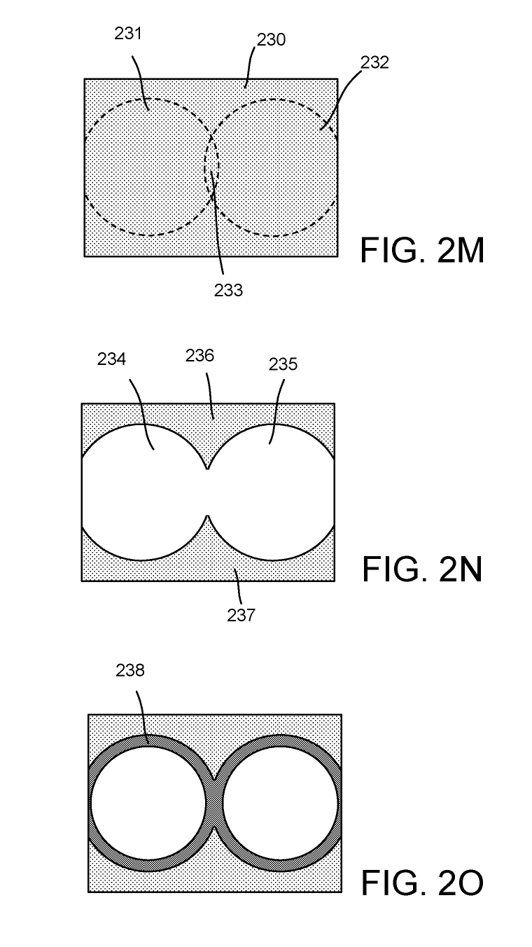

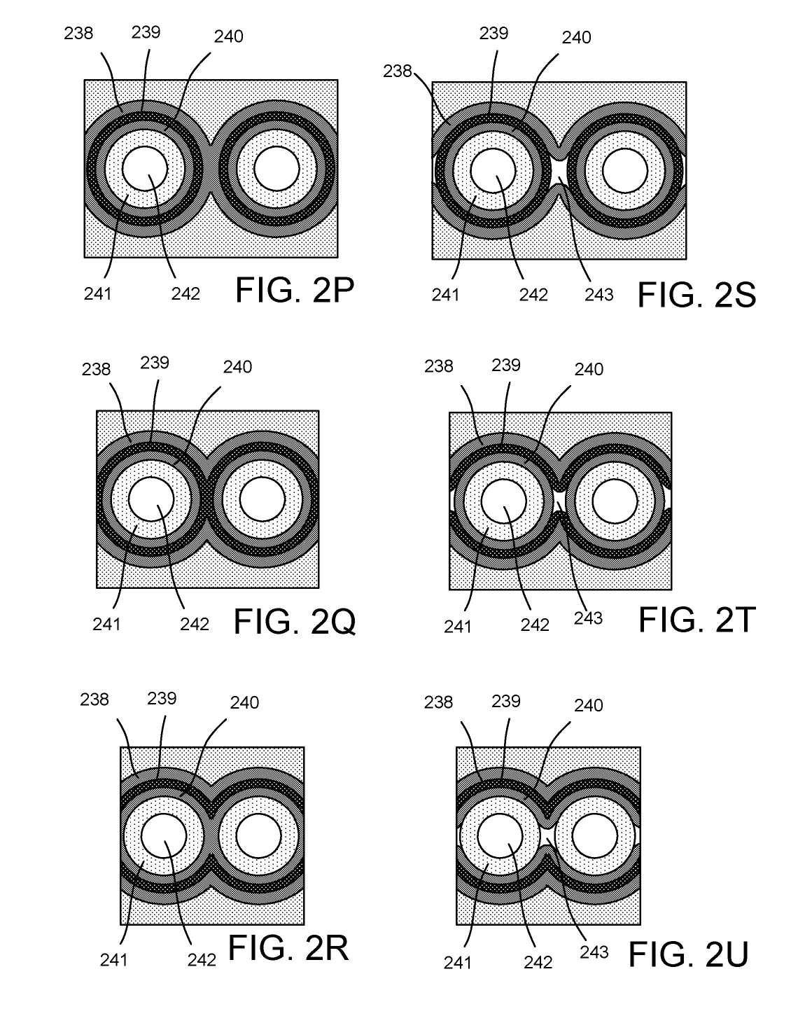

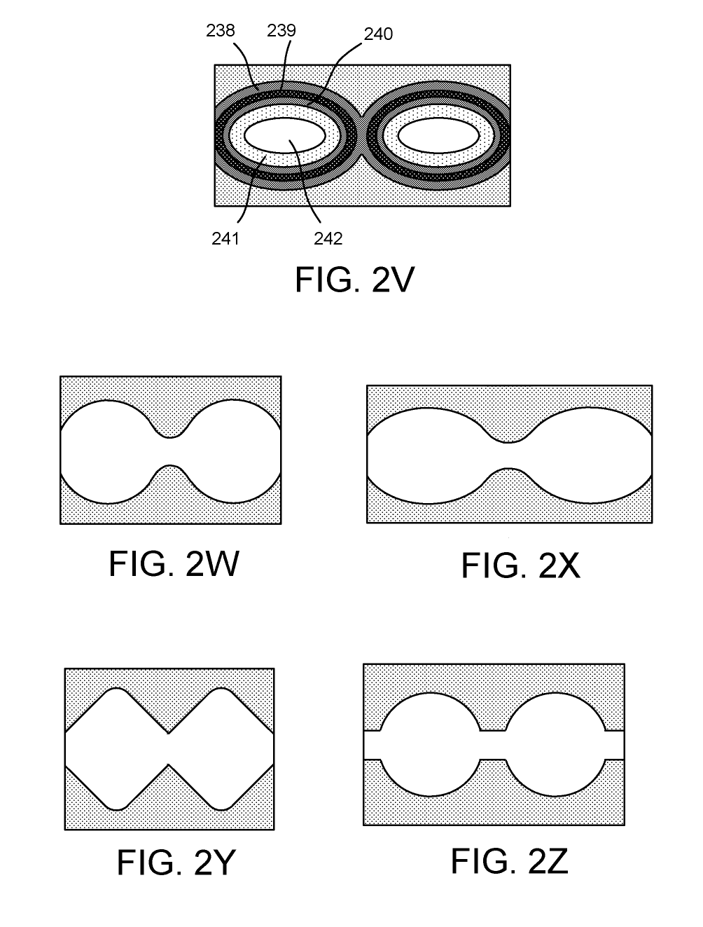

FIG. 2A shows an exemplary embodiment of a novel 3D Double-Density (DD) NAND flash memory. The 3D DD NAND includes multiple polysilicon or metal layers (ML) that function as word lines (WL), such as WL 200 and ML 201. Insulation layers (e.g., 202), such as an oxide, are positioned between the metal layers (word lines) to form a stacked configuration. A silicon region 203 (or polysilicon) runs vertically in etched openings (e.g., 250) and functions as the NAND string's cell channel. A charge-trapping layer 204, such as an ONO (Oxide-Nitride-Oxide) layer, is used to trap electrons or holes for data storage. Each storage cell is formed in the intersection of a WL layer and the charge-trapping layer of a NAND string. The string cell channel may or may not contain an insulator layer 208 such as oxide in the center of the string cell channel, depending on the technology. Such variations are within the scope of the embodiments.

In various exemplary embodiments, the 3D DD NAND includes ‘slits’ (as illustrated at 205) that are etched through all word line layers. The slits may be filled with an insulator such as an oxide. In another embodiment, the slits 205 may remain vacant without any filling material. These slits separate (or divide) the word lines in each layer that surround the cell channels. As a result, the charge-trapping layer 204 of each cell channel is coupled to (or interfaces with) two word line regions in each WL layer. The two word line regions allow the cell channel to store two bits of data in the charge trapping layer, as shown at 206 and 207. For example, the intersection of each word line region and a charge trapping layer forms a cell storage region. Since each charge trapping layer intersects with two word line regions (due to the slit locations), two cell storage regions are formed that can store two bits of data, respectively. Therefore, in an SLC structure, the 3D DD NAND cell can store two data bits per cell, and in the MLC or TLC structures, the 3D DD NAND cell can store 4 and 6 bits per cell, respectively. Thus, the word line slits enable the cell channels to store double the number of data bits over a conventional NAND flash memory without increasing the area of the array.

In accordance with the exemplary embodiments, the novel 3D Double-Density (DD) NAND flash memory includes at least the following features.
1. A three dimensional stacked configuration of word line layers and insulating layers. The layers are stacked in the Z direction for a particular number of layers or height.
2. An array of etched (drilled or otherwise formed) openings in the stack configuration extending perpendicularly from the top surface for the entire height of the stack.
3. NAND strings deposited in the etched openings.
4. The NAND strings comprising:
a central polysilicon tube extending for the height of the stack,
a charge-trapping layer deposited around the polysilicon tube and extending for the height of the stack, and
an oxide insulator that fills the interior of the polysilicon tube.
5. NAND storage cells are formed at the intersection of the word line layers and the charge-trapping layers such that signals on the word line layers control storage of electric charge in the charge-trapping layer. Each cell stores charges representing one bit of data.
6. One or more slits that split the word lines to form two charge-trapping regions at each layer for each NAND string, thereby forming two storage cells and doubling data storage.

FIG. 2B shows an exemplary embodiment illustrating how the slits in the 3D DD NAND cell are used to configure how the cell channels connect to the word lines. For example, the word lines in each layer may be connected to the cell channels by the slit pattern 220 shown in FIG. 2B. As a result of the connection pattern shown in FIG. 2B, each metal layer (or level) contains two word lines (e.g., word line regions). For example, on a first level, metal layer portion 211 forms a left word line (WLL0) and metal layer portion 215 forms a right word line (WLR0). Similarly, metal layer portions 212, 213, and 214 form the left word lines WLR1-3 for the second, third, and fourth levels, respectively. Furthermore, metal layer portions 216, 217, and 218 form the right word lines WLR1-3 for the second, third, and fourth levels, respectively. As a result, on each level of the 3D DD NAND, each cell channel is coupled to one left word line and one right word line, thus forming two cell storage regions, which allows the charge-trapping layer around each cell channel to store two data bits (e.g., one bit for each word line region).

FIG. 2C shows another exemplary embodiment of the 3D DD NAND array structure. The array shown in FIG. 2C is similar to the array shown in FIG. 2B but manufactured using different process steps to yield a different word line connection pattern to the cell channels. In this embodiment, the NAND string cell channels and the word line slits are etched in the same process step, instead of in two steps used to create the configuration shown in FIG. 2B. In this embodiment, the slits (illustrated at 209) are filled with the charge-trapping material, such as ONO, rather than oxide as in FIG. 2A.

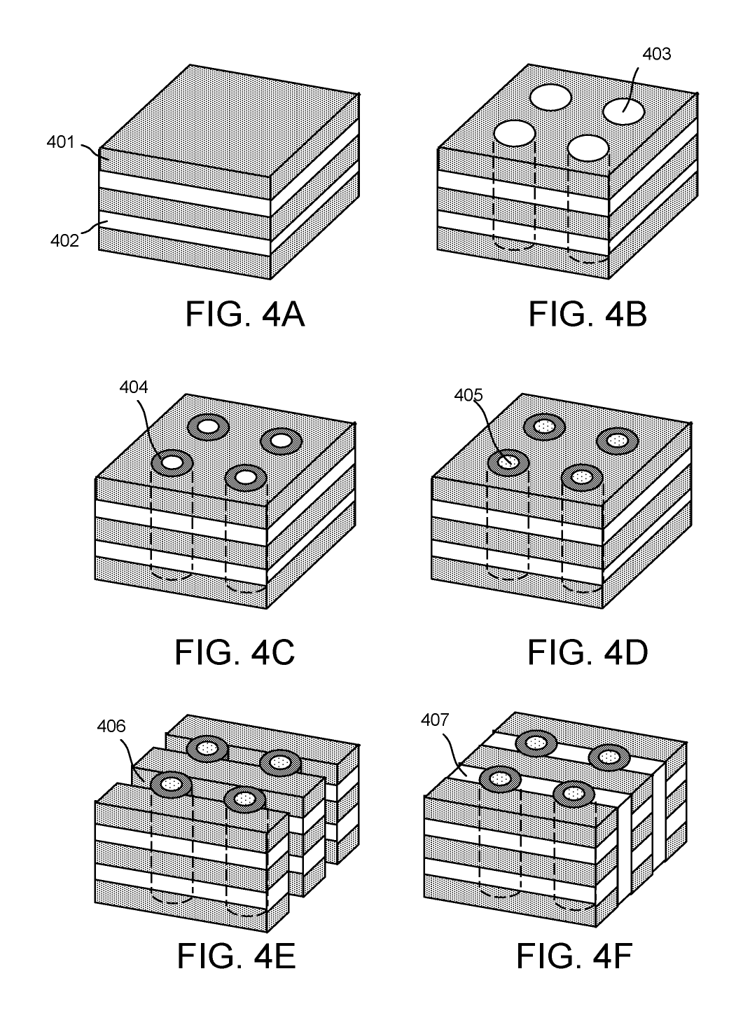

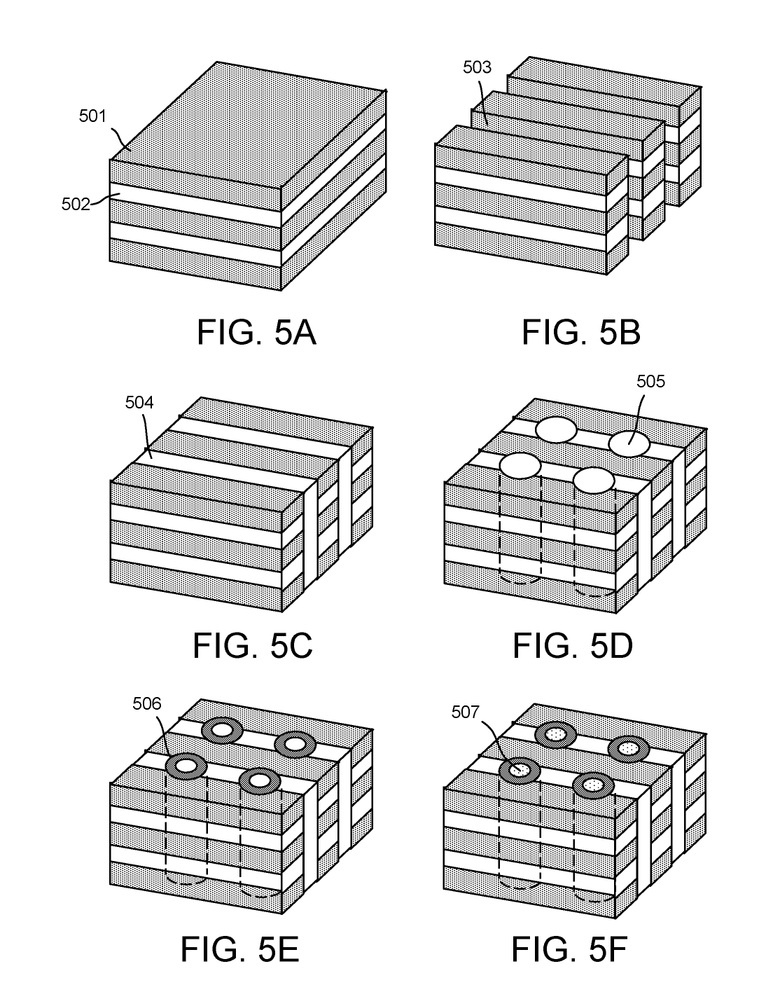

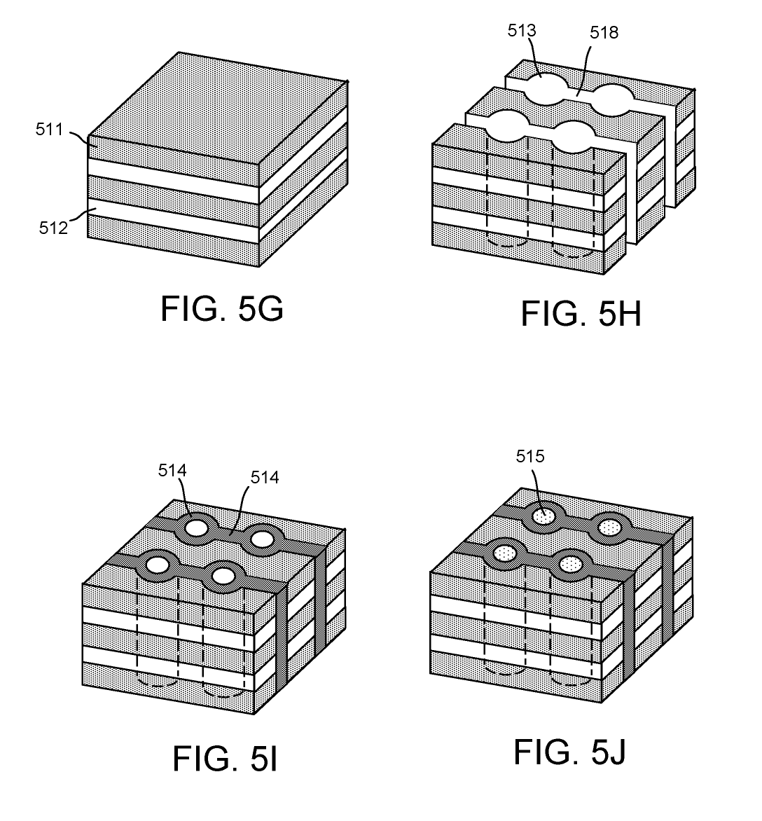

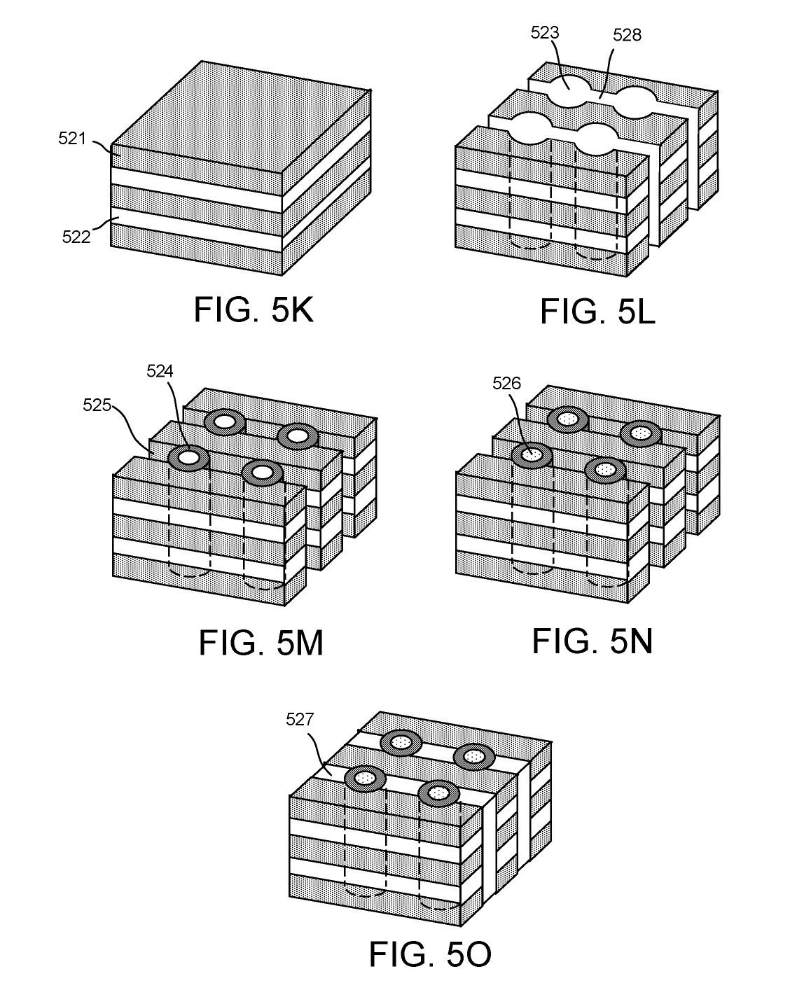

FIG. 2D shows another exemplary embodiment of the 3D DD NAND array structure. In this embodiment, the NAND string cell channels and word line slits are etched in the same process step. However, the slits (illustrated at 210) remain vacant after etching while the cell channels are filled with the charging trapping layer 204. In still another embodiment, the slits 210 can be filled with insulating material such as oxide. After filling, the array will look like the one shown in FIG. 2A. Similar to FIG. 2A, each cell channel in each word line layer is coupled to two word line regions on two sides, and thus one storage cell can store two bits of data, as shown at 206 and 207. Additional details about the process steps used to produce the array shown in FIG. 2D are provided below with reference to FIGS. 4A-5J. It should also be noted that in various embodiments, the NAND string cell channels and the word line slits can be arranged in many different ways, as exemplified by the embodiments shown in FIGS. 2E-2H.

FIG. 2E shows an exemplary embodiment of a cell channel arrangement where the cell channels (e.g., illustrated at 211) are arranged in a rectangular pattern and the slits (e.g., illustrated at 209) are arranged as straight line regions that intersect the cell channels. In this configuration, the charge-trapping layer 204 of cell 211 is coupled to two word line regions (e.g., 212 and 213) on two sides and thus can store two bits of data (206 and 207) as shown.

FIG. 2F shows another embodiment of a cell channel arrangement where the cell channels (e.g., illustrated at 211) are arranged in stagger positions relative to one another. This arrangement can reduce the vertical pitch between rows of cell channels by approximately 13-14%. In this embodiment, the slits (illustrated at 209) are arranged as straight line regions similar to FIG. 2E.

FIG. 2G and FIG. 2H show other embodiments of a cell channel arrangement where the slits are formed in serrated (or diagonal) patterns. For example, in FIGS. 2G and 2H, the slits (e.g., illustrated at 209) cut across cell channels in different rows to form the word line regions 212 and 213. It should be noted that the various string cell channel and word line slit patterns shown herein are just exemplary and that there is virtually no limit on the types of patterns that may be used within the scope of the embodiments. It should also be noted that the slits of the various exemplary embodiments, may be filled by an insulator, such as oxide, remain vacant, or be filled with the charge-trapping layers, such as ONO layers. This may be done by the same process steps used to form the charge-trapping layers in the string cell channels to reduce the manufacturing cost.

FIGS. 2I-2L shows several exemplary cell channel configurations after the slit filling operation is performed. FIG. 2I shows a first cell channel configuration where the charge-trapping layers are completely filled and flow into the slits between cell channels. Thus, the slits contain the first dielectric layer such as oxide 220, a charge-trapping layer such as nitride 221, and a second dielectric layer such as tunnel oxide 222. A polysilicon cell channel 223 and an insulating layer 224 in the cell channels are also shown. The insulating layer 224 may be an oxide. In another embodiment, the insulating layer 224 may be removed or left vacant.

FIG. 2J shows another exemplary cell channel configuration where the slits are only filled between the cell channels by the first dielectric layer 225, which may be a tunneling oxide. FIG. 2K shows another exemplary cell channel configuration where there is a ‘void’ 227 formed inside the slits after the first dielectric layer 226 is filled in.

FIG. 2L shows another exemplary cell channel configuration where the entire slit 228 may remain void of material. It should be noted that for all of the configurations shown above, the NAND string's cell channels still operate successfully to provide double the data storage. Therefore, the slit filling process steps will not cause yield loss concern in manufacturing.

FIGS. 2M-2U show exemplary embodiments of cell channel configurations where the separated left-WL and right-WL word line patterns are formed by lithography of the bit line cell channels. Referring to the configuration in FIG. 2M, the word line layer 230 may be polysilicon or metal and include two adjacent bit line cell channels 231 and 232. The two bit line cell channels 231 and 232 are placed closely together and have an overlapping region 233.

FIG. 2N shows the cell channel configuration of FIG. 2M illustrating the word line layer 230 after the bit line cell channels 231 and 232 are etched. The two bit line cell openings 234 and 235 are connected together and cut the word line layer 230 to form two word lines 236 and 237.

FIG. 2O shows the cell channel configuration of FIG. 2N illustrating the bit line cell openings after the first dielectric layer 238, such as oxide, is deposited on the inside surface.

FIG. 2P shows an exemplary embodiment of the completed bit line cell channel pattern shown in FIG. 2O after forming the charge-trapping layer 239, such as nitride, the second dielectric layer 240, such as tunnel oxide, the polysilicon channel 241, and the insulator core 242, such as oxide, on the inside surfaces of the cell channels. It should be noted that the resulting bit line cell channel pattern may depend on the distance, shape, overlapping area, and process associated with the formation of the bit line cell channels.

FIG. 2Q shows another exemplary embodiment of the completed bit line cell channel pattern shown in FIG. 2O where the first dielectric layer 238 and the charge-trapping layer 239 are connected between two adjacent bit line cell channels.

FIG. 2R shows another exemplary embodiment of the completed bit line cell channel pattern shown in FIG. 2O where the first dielectric layer 238 and the charge-trapping layer 239, and the tunnel oxide layer 240 are connected between two adjacent bit line cell channels.

FIG. 2S, FIG. 2T, and FIG. 2U are similar to FIG. 2P, FIG. 2Q, and FIG. 2R, respectively, except that in FIG. 2S, FIG. 2T, and FIG. 2U there is a void 243 formed between the bit line cell channels.

It should also be noted that in various exemplary embodiments, the bit line cell channels are not limited to having a circular shape. In fact, the bit line cell channels may form any shapes that are suitable for the purpose of forming the separated word line patterns. For example, in FIG. 2V the bit line cell channels are formed using an oval shape. FIG. 2W, FIG. 2X, FIG. 2Y, and FIG. 2Z show additional examples of possible bit line cell channel shapes (e.g., ovals, triangles, circles).

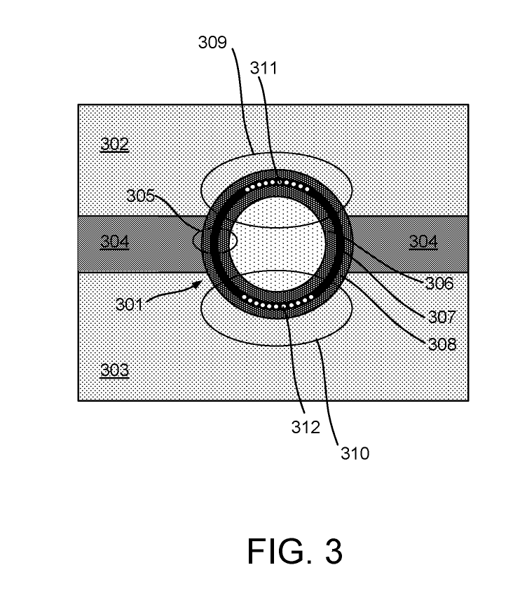

FIG. 3 shows an exemplary embodiment of a 3D DD NAND cell channel that illustrates how multiple bits are stored at charge storing regions associated with each NAND string cell channel. As shown in FIG. 3, word line regions 302 and 303 are formed as a result of the slit 304. In an exemplary embodiment, the word lines 302 and 303 are formed from a metal layer and the slit 304 splits the metal layer to form the two separate word line regions. The cell channel 301 includes a storage region 305 that comprises a first dielectric material 308, a charge-trapping material 307 and a second dielectric material 306. Thus, in an exemplary embodiment, the storage region 305 comprises ONO material. The word line 302 contacts the storage region 305 at a first interface region 309 and the word line 303 contacts the storage region 305 at a second interface region 310. The split word lines resulting from the slit 304 allow charge to be stored at each interface region. For example, in region 309, charge is stored in the charge-trapping material 307 by operation of the word line 302 as illustrated at 311, and in region 310, charge is stored in the charge-trapping material 307 by operation of the word line 303 as illustrated at 312. The stored charge represents data bits and thus each cell can store two data bits, which is double the density of conventional 3D NAND cells.

FIGS. 4A-F shows exemplary embodiments of process steps used to form the 3D DD NAND array structure shown in FIG. 2A.

In a first operation shown in FIG. 4A, multiple conductor layers 401, such as polysilicon or metal layers, are deposited between insulator layers 402, such as oxide, to form 3D stacked word lines with insulation layers in between.

In a second operation shown in FIG. 4B, multiple cell channel openings ‘holes’ 403 for NAND strings are patterned and etched through all the word line 401 and insulator 402 layers.

In a third operation shown in FIG. 4C, charge-trapping layers 404, such as ONO layers, are formed on the sidewalls of the cell channels 403.

In a fourth operation shown in FIG. 4D, silicon or polysilicon 405 are deposited to fill the cell channels. The silicon or polysilicon 405 may or may not be doped according to the technology used.

In a fifth operation shown in FIG. 4E, ‘slits’ 406 are patterned and etched through all the word line 401 and insulator 402 layers to form a configuration where for each metal layer each cell interfaces with two word line regions. The etching chemical solution may be material-selective so it does not etch through the charge-trapping layers on the cell channel sidewalls.

In a sixth operation shown in FIG. 4F, insulator material 407, such as oxide, is deposited to fill the slits 406. It should be noted that in other embodiments, the slits 406 may remained vacant without filling materials. It should also be noted that according to some technologies, there may be dielectric layers, such as oxide, in the center of each NAND string's cell channel. For these technologies, the dielectric layer may be filled in after the process step shown in FIG. 4F.

FIGS. 5A-F shows an exemplary embodiment of process steps to form the 3D DD NAND array structure shown in FIG. 2A.

In a first operation shown in FIG. 5A, multiple conductor layers 501, such as polysilicon or metals and insulator layers 502, such as oxide, are deposited to form 3D stacked word lines with insulation layers in between.

In a second operation shown in FIG. 5B, multiple slits 503 are patterned and etched through all the word lines and insulator layers.

In a third operation shown in FIG. 5C, the slits are filled with insulator material such as oxide. Please notice, in another embodiment according to the invention, the slits 503 may be remained vacant without filling material.

In a fourth operation shown in FIG. 5D, multiple cell channel openings ‘holes’ 505 for NAND strings are patterned and etched through all the word line 501 and insulator 502 layers.

In a fifth operation shown in FIG. 5E, charge-trapping layers 506, such as ONO layers, are formed on the sidewall of the cell channel openings 505.

In a sixth operation shown in FIG. 5F, silicon or polysilicon 507 is deposited to fill the cell channels. The silicon or polysilicon 507 may or may not be doped according to the technology used.

FIGS. 5G-J shows an exemplary embodiment of process steps to form the 3D DD NAND array structure shown in FIG. 2A.

In a first operation shown in FIG. 5G, multiple conductor layers 511, such as polysilicon or metals and insulator layers 512, such as oxide, are deposited to form 3D stacked word lines with insulation layers in between.

In a second operation shown in FIG. 5H, multiple slits 518 and multiple cell channel openings ‘holes’ 513 for NAND strings are patterned and etched through all the word lines and insulator layers.

In a third operation shown in FIG. 51, the slits 518 and the cell channel openings 513 are filled with charge-trapping material 514, such as ONO layers.

In a fourth operation shown in FIG. 5J, silicon or polysilicon 515 is deposited to fill the cell channels. The silicon or polysilicon 515 may or may not be doped according to the technology used.

FIGS. 5K-O shows an exemplary embodiment of process steps to form the 3D DD NAND array structure shown in FIG. 2A.

In a first operation shown in FIG. 5K, multiple conductor layers 521, such as polysilicon or metals and insulator layers 522, such as oxide, are deposited to form 3D stacked word lines with insulation layers in between.

In a second operation shown in FIG. 5L, multiple slits 528 and multiple cell channel openings ‘holes’ 523 for NAND strings are patterned and etched through all the word lines and insulator layers.

In a third operation shown in FIG. 5M, the cell channel openings 523 are filled with charge-trapping material 524, such as ONO layers. The slits 528 are not filled with material as illustrated at 525.

In a fourth operation shown in FIG. 5N, silicon or polysilicon 526 is deposited to fill the cell channels. The silicon or polysilicon 526 may or may not be doped according to the technology used.

In a fifth operation shown at FIG. 50, the slits 528 are filled with insulator material such as oxide.

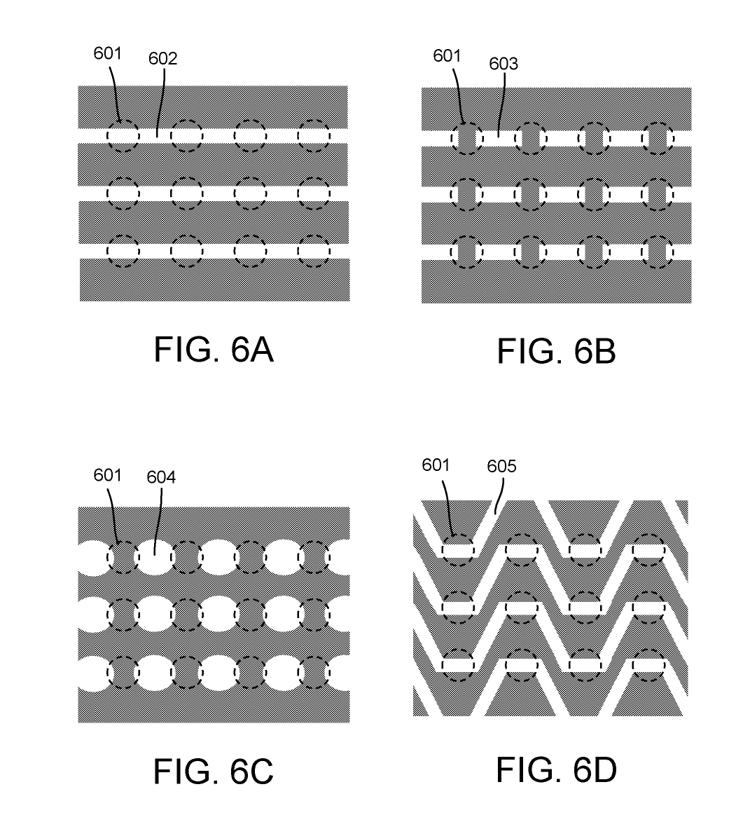

FIGS. 6A-6D show exemplary embodiments of word line ‘slit’ patterns for use with embodiments of the 3D DD NAND array. The dash line circles 601 indicate the NAND string cell channels. It should be noted that the shape of the cell channels are not limited to being circles and can comprise any other shape, such as oval, square, rectangular, or triangle.

FIG. 6A shows an exemplary embodiment where the slits comprise straight lines regions (e.g., 602) that cross all string cell channels in each row. FIG. 6B shows an exemplary embodiment where the slits comprise short segment regions (e.g., 603) between the string cell channels in a row. FIG. 6C shows an exemplary embodiment where the slits comprise oval shaped regions 604 between the string cell channels in a row. FIG. 6D shows an exemplary embodiment where the slits comprise zig-zag segment regions 605 that cross the string cell channels across different rows. It should be noted that the slit patterns shown in FIGS. 6A-6D are exemplary and that other patterns may be used within the scope of the embodiments.

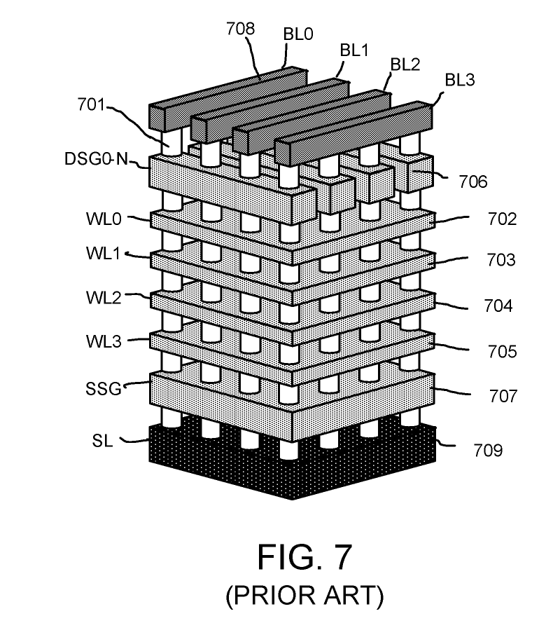

FIG. 7 shows a conventional 3D NAND flash memory array structure. The array structure includes multiple vertical NAND strings (e.g., 701), word lines 702, 703, 704, and 705, multiple drain select gates (e.g., 706), source select gate 707, multiple bit lines (e.g., 708), and source line 709. The NAND strings (701-704) are selected by the drain select gates (DSG0-3) to connect to the bit lines (BL0-3) for read and write operations. It should be noted that the drain select gates (DSG0-3) and the source select gate 707 may have longer channel length than the cells in order to sustain high program voltage.

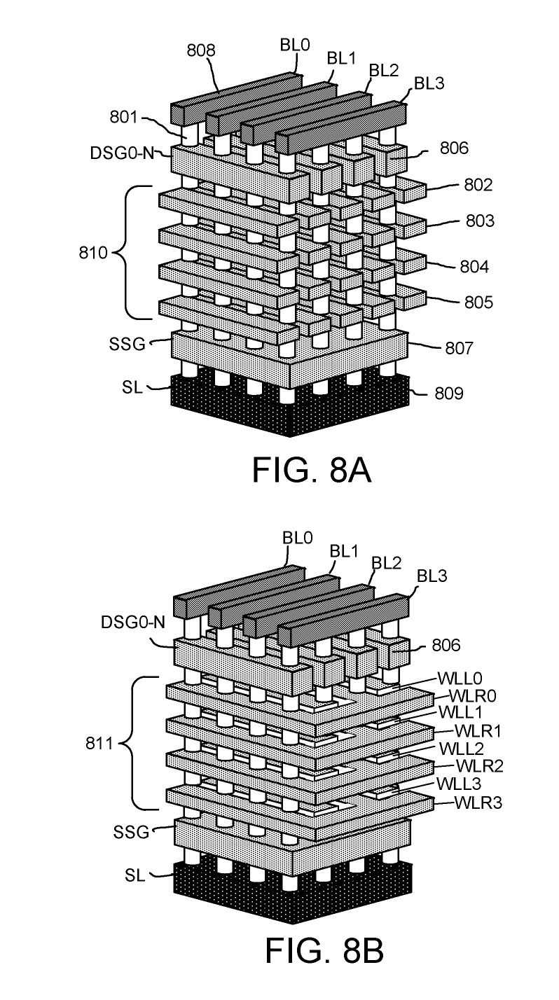

FIGS. 8A-B show exemplary embodiments of 3D Double-Density NAND flash memory array structures.

FIG. 8A shows an exemplary embodiment of split word lines in a 3D Double-Density NAND flash memory array structure. The array structure shown in FIG. 8A includes multiple vertical NAND strings (e.g., 801), split word line layers 802, 803, 804, and 805, drain select gates (DSG0-3) (e.g., 806), source select gate 807, bit lines (BL0-3) (e.g., 808), and source line 809. The NAND strings 801 are selected by the drain select gates 806 to connect to the bit lines 808 for read and write operations. As illustrated in FIG. 8A, the word line layers 802-805 are formed as split layers in accordance with the exemplary embodiments above. For example, each word line layer is split into multiple word line regions using “slits” as described above, such that in each layer, charge-trapping regions of the NAND string cell channels contact two word line regions to enable storage of two data bits in the strings' charge-trapping material. For example, the region shown at 810 can be implemented as shown in FIG. 2D where two word line regions are coupled on two sides of the cells. This allows for each cell to store double the data as shown at 206 and 207. Similarly, the “cells” of the NAND strings 801 in FIG. 8A can also provide two bits of storage as a result of the split word lines. It should be noted that the drain select gates (DSG0-3) 806 and the source select gate 807 may have longer channel length than the cells in order to sustain high program voltage.

FIG. 8B shows an exemplary embodiment of connected word line regions in a 3D Double-Density NAND flash memory array structure. The array structure shown in FIG. 8B includes connections between even and odd word lines regions. For example, word line connections are made to form left word lines WLL0-3 and right word lines WLR0-3. Thus, in each layer, each cell's two bits can be read independently by the selection of left word lines or right word lines. For example, the region shown at 811 can be implemented as shown in FIG. 2B where separated word line regions are connected to form left word lines (WLL) and right word lines (WLR) to allow storage and retrieval of two data bits for each cell.

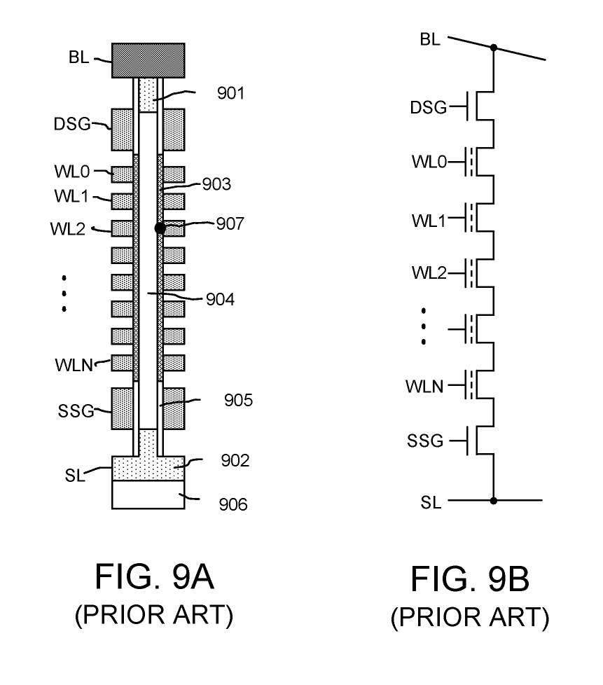

FIGS. 9A-B shows structural and schematic views of a conventional 3D NAND cell string.

FIG. 9A shows a cross-sectional view of the conventional NAND cell string structure. As illustrated in FIG. 9A, the conventional string structure includes diffusion regions 901, 902 that may have P-type or N-type doping, depending on the technology used. Also shown is a charge-trapping layer 903, such as ONO, a silicon or polysilicon 904 that serves as the cells' channel, a gate oxide 905 or high-K dielectric of the drain and source select gates, and a substrate 906. Because each word line surrounds the entire cell string, each cell can only store one data bit in the charge-trapping layer 903, for example, WL2 can be used to store one data bit 907 in the charge-trapping layer 903.

FIG. 9B shows the equivalent circuit of the conventional NAND string structure illustrated in FIG. 9A. As shown, each word line provides for storage of only one data bit.

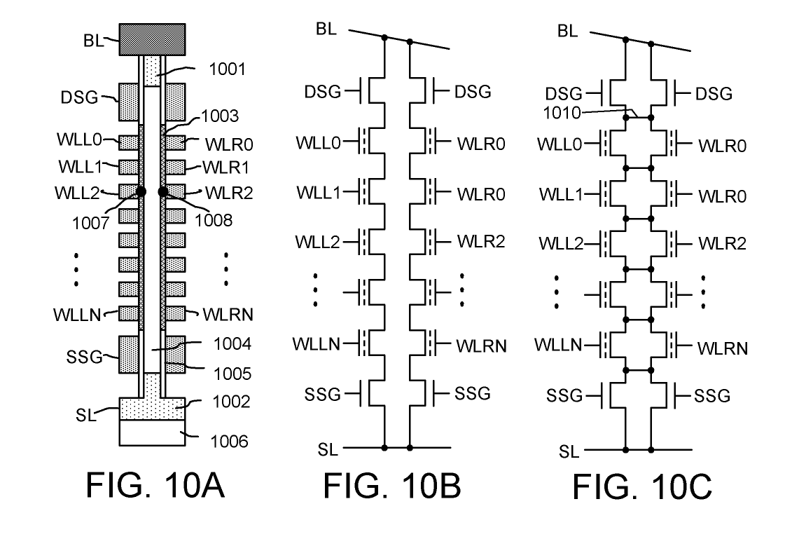

FIGS. 10A-C shows structural and schematic views of a 3D Double-Density NAND cell string.

FIG. 10A shows a cross-sectional view of the 3D Double-Density NAND cell string structure. As illustrated in FIG. 10A, the 3D DD NAND string structure includes diffusion regions 1001, 1002 that may have P-type or N-type doping, depending on the technology used. Also shown is a charge-trapping layer 1003, such as ONO, a silicon or polysilicon 1004 that serves as the cells' channel, a gate oxide 1005 or high-K dielectric of the drain and source select gates, and a substrate 1006. In accordance with the various embodiments, each cell is coupled to a left word line WLL and a right word line WLR. As illustrated in FIG. 10A, splitting the word lines to form odd and even connections allows each cell to store two data bits in the charge-trapping layers. For example WLL2 can be used to store a first data bit 1007 in the charge-trapping layer 903 and WLR2 can be used to store a second data bit 1008 in the charge-trapping layer 903. This effectively doubles the storage capacity of the cell without increasing the array size.

FIG. 10B shows an exemplary schematic of an equivalent circuit of the 3D DD NAND cell string structure shown in FIG. 10A. It should be noted that although the physical structure shown in FIG. 10A illustrates only one cell string, due to the separated left and right word line structures, each cell string can be represented by two circuits. For example, a first circuit is coupled to the left word lines (WLL) and a second circuit is coupled to the right word lines (WLR). The two strings may be selected by the same source select gate SSG, and drain select gate DSG.

For larger-scale devices, the two strings' channel regions formed under their control gates may not touch, thus the two strings are separated as shown FIG. 10B. However, when the device size is scaled down, the channels formed by the two strings may touch each other, thus the equivalent circuit becomes that shown in FIG. 10C. For each cell, their source and drain nodes become shorted together as shown at 1010. This will not affect the operations of the NAND string. However, during read operation, when one cell's left or right word line is selected, a voltage should be applied to its unselected word line to turn off the unselected bit, otherwise it may cause leakage current if the bit's Vt is negative. For unselected word lines, a voltage higher than the off cell's Vt is applied to pass the cell current of the selected cell.

While particular embodiments of the present invention have been shown and described, it will be obvious to those of ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. An apparatus, comprising:
a three dimensional stacked configuration of word line layers separated by insulating layers, wherein the stacked configuration includes a selected number of the word line layers;
an array of etched openings in the stacked configuration extending perpendicularly from a top surface through the selected number of word line layers;
an array of NAND strings deposited within the etched openings, wherein each NAND string includes a charge-trapping layer that extends through the selected number of word line layers; and
one or more slits through the stacked configuration that divide each word line layer into a plurality of word line regions, and wherein each charge-trapping layer is coupled to two word line regions in each word line layer to form two charge-trapping regions to store two data bits in each word line layer.

2. The apparatus of claim 1, wherein the word line layers comprise metal layers.

3. The apparatus of claim 1, wherein the insulating layers comprise oxide layers

4. The apparatus of claim 1, wherein the charge-trapping layers of each NAND string comprise an Oxide-Nitride-Oxide (ONO) material.

5. The apparatus of claim 1, wherein each NAND string includes a cell channel that is center-filled with an oxide material.

6. The apparatus of claim 1, the apparatus forming a three dimensional double density flash memory.

7. The apparatus of claim 1, wherein the one or more slits are filled with an insulating material.

8. The apparatus of claim 1, wherein the one or more slits are filled with a charge-trapping material.

9. The apparatus of claim 1, wherein the plurality of word line regions in each word line layer are connected to form a left word line and a right word line.

10. The apparatus of claim 1, wherein the array of NAND strings comprises NAND strings arranged in a rectangular configuration.

11. The apparatus of claim 1, wherein the array of NAND strings comprises NAND strings arranged in a staggered configuration.

12. The apparatus of claim 1, wherein the one or more slits through the stacked configuration remove word line material between NAND strings along a common row.

13. The apparatus of claim 1, wherein the one or more slits through the stacked configuration remove word line material between NAND strings in different rows.

14. A method for generating a three-dimensional storage device, comprising:
depositing multiple word line layers and insulating layers to form a three dimensional stacked configuration of the word line layers separated by the insulating layers, wherein the stacked configuration includes a selected number of the word line layers;
etching openings in the stacked configuration extending perpendicularly from a top surface through the selected number of word line layers;
depositing cell channels in the etched opening, wherein the cell channels include charge-trapping layers; and
etching slits through the stacked configuration to divide each word line layer into a plurality of word line regions, and wherein each charge-trapping layer is coupled to two word line regions in each word line layer to form two charge-trapping regions to store two data bits in each word line layer.

15. The method of claim 14, further comprising depositing polysilicon in the center of the cell channels.

16. The method of claim 14, further comprising depositing oxide in the slits.

17. The method of claim 14, wherein the operation of etching comprises etching the slits to remove word line layer material between openings along a common row.

18. The method of claim 14, wherein the operation of etching comprises etching the slits to remove word line layer material between openings in different rows.
